(19) United States
(12) Patent Application Publication
(10) Pub. No.: US 2026/0150349 A1
(43) Pub. Date: May 28, 2026

(54) WIDE BANDGAP POWER DEVICE WITH SELF-ALIGNED OHMIC SILICIDED REGIONS

(71) Applicant: Wolfspeed, Inc., Durham, NC (US)

(72) Inventors: Thomas Harrington, Carrollton, TX (US); Shadi Sabri, Apex, NC (US)

(21) Appl. No.: 18/961,973

(22) Filed: Nov. 27, 2024

(51) Int. Cl. H10D 30/69; H10D 30/01; H10D 64/62; H10D 64/66

(52) U.S. Cl. CPC H10D 30/794; H10D 30/0293; H10D 64/62; H10D 64/668; H10D 64/675

(57) ABSTRACT

A power semiconductor device includes a semiconductor layer structure having a drift region of a first conductivity type, and a gate structure including a gate contact on the semiconductor layer structure and a silicide blocking layer on the gate contact opposite the semiconductor layer structure. A protective spacer is provided on a sidewall of the gate structure, where the protective spacer is directly on the semiconductor layer structure. The protective spacer may define an interface with the semiconductor layer structure that is free of a gate insulating layer therebetween. Related devices and fabrication methods are also discussed.

### FIELD

The present invention relates to semiconductor devices and, more particularly, to power semiconductor devices.

### BACKGROUND

Power semiconductor devices are used to carry large currents and support high voltages. A wide variety of power semiconductor devices are known in the art including, for example, power Metal Insulator Semiconductor Field Effect Transistors (“MISFETs,” including Metal Oxide Semiconductor FETs (“MOSFETs”)), bipolar junction transistors (“BJTs”), Insulated Gate Bipolar Transistors (“IGBT”), Junction Barrier Schottky diodes, Gate Turn-Off Transistors (“GTO”), MOS-controlled thyristors, and various other devices. These power semiconductor devices are generally fabricated from wide bandgap semiconductor materials, for example, silicon carbide (“SiC”) or Group III nitride (e.g., gallium nitride (“GaN”))-based semiconductor materials. Herein, a wide bandgap semiconductor material refers to a semiconductor material having a bandgap greater than about 1.40 eV, for example, greater than about 2 eV.

A conventional power semiconductor device typically has a semiconductor substrate having a first conductivity type (e.g., a n-type substrate) on which an epitaxial layer structure having the first conductivity type (e.g., n-type) is formed. A portion of this epitaxial layer structure (which may comprise one or more separate layers) functions as a drift layer or drift region of the power semiconductor device. The device typically includes an “active region,” which includes one or more “unit cell” structures that have a junction, for example, a p-n junction. The active region may be formed on and/or in the drift region. The active region acts as a main junction for blocking voltage in the reverse bias direction and providing current flow in the forward bias direction. The power semiconductor device may also have an edge termination in a termination region that is adjacent the active region. One or more power semiconductor devices may be formed on the substrate, and each power semiconductor device will typically have its own edge termination. After the substrate is fully processed, the resultant structure may be diced to separate the individual edge-terminated power semiconductor devices.

Power semiconductor devices may have a unit cell configuration in which a large number of individual unit cell structures of the active region are electrically connected in parallel to function as a single power semiconductor device. In high power applications, such a power semiconductor device may include thousands or tens of thousands of unit cells implemented in a single chip or “die.” A die or chip may include a small block of semiconducting material or other substrate in which electronic circuit elements are fabricated.

Power semiconductor devices are designed to block (in the forward or reverse blocking state) or pass (in the forward operating state) large voltages and/or currents. For example, in the blocking state, a power semiconductor device may be designed to sustain hundreds or thousands of volts of electric potential. As the applied voltage approaches or passes the voltage level that the device is designed to block, non-trivial levels of current (referred to as leakage current) may begin to flow through the power semiconductor device. The blocking capability of the device may be a function of, among other things, the doping density/concentration and thickness of the drift region. Leakage currents may also arise for other reasons, such as failure of the edge termination and/or the primary junction of the device. If the voltage applied to the device is increased past the breakdown voltage to a critical level, the increasing electric field may result in an uncontrollable and undesirable runaway generation of charge carriers within the semiconductor device, leading to a condition known as avalanche breakdown.

Power semiconductor devices can have a lateral structure or a vertical structure. In a device having a lateral structure, the terminals of the device (e.g., the drain, gate and source terminals for a power MOSFET device) are on the same major surface (e.g., top or bottom) of a semiconductor layer structure. In contrast, in a device having a vertical structure, at least one terminal is provided on each major surface of the semiconductor layer structure (e.g., in a vertical MOSFET device, the source may be on the top surface of the semiconductor layer structure and the drain may be on the bottom surface of the semiconductor layer structure). The semiconductor layer structure may or may not include an underlying substrate. Herein, the term “semiconductor layer structure” refers to a structure that includes one or more layers, for example, semiconductor substrates and/or semiconductor epitaxial layers. In SiC-based power devices, a same silicide metal (or metals) and a same silicide anneal scheme may typically be used to form contacts to the terminals of the device.

Power semiconductor devices including wide-bandgap semiconductor materials, such as SiC, may require one or more silicide layers to be formed on the surface of heavily-doped junction regions (e.g., N+ and P+ regions) in order to provide good ohmic contact (i.e., a non-rectifying, low-resistance contact) to those regions by a subsequent metallization, which is used to apply voltage and current (often with high-current density) to those junction regions.

### SUMMARY

According to some embodiments, a power semiconductor device includes a semiconductor layer structure including a drift region of a first conductivity type, a gate structure including a gate contact on the semiconductor layer structure and a silicide blocking layer on the gate contact opposite the semiconductor layer structure, and a protective spacer on a sidewall of the gate structure, where the protective spacer is directly on the semiconductor layer structure. The protective spacer may define an interface with the semiconductor layer structure that is free of a gate insulating layer therebetween.

In some embodiments, the protective spacer may include a different material than the silicide blocking layer.

In some embodiments, the protective spacer extends onto a sidewall of the silicide blocking layer.

In some embodiments, the gate structure may include first and second gate structures on the semiconductor layer structure with at least one source region therebetween, and the protective spacer may include first and second protective spacers on adjacent sidewalls of the first and second gate structures, respectively. The power semiconductor device may further include a first conductive silicide on the at least one source region and continuously extending from the first protective spacer to the second protective spacer.

In some embodiments, an interlayer dielectric layer is on the first and second gate structures and may include an opening therein that exposes the at least one source region, where the first conductive silicide extends beyond edges of the at least one opening in the interlayer dielectric layer such that the first conductive silicide is between the interlayer dielectric layer and the semiconductor layer structure.

In some embodiments, the semiconductor layer structure may further include a well contact region of a second conductivity type between the first and second gate structures, and the first conductive silicide may be on the well contact region.

In some embodiments, the silicide blocking layer extends on the sidewall between the gate contact and the protective spacer.

In some embodiments, the protective spacers may include respective widths that are configured to electrically isolate the gate contacts from edges of the first conductive silicide.

In some embodiments, the protective spacer may include first and second layers of different dielectric materials.

In some embodiments, the gate contact may include polysilicon and is free of the first conductive silicide.

In some embodiments, the gate contact may further include a second conductive silicide between the polysilicon and the silicide blocking layer, where the second conductive silicide is different from the first conductive silicide.

In some embodiments, the semiconductor layer structure may include silicon carbide, the first conductive silicide may include nickel, and the second conductive silicide may include at least one of tantalum, tungsten, titanium, or cobalt.

According to some embodiments, a power semiconductor device includes a semiconductor layer structure including a drift region of a first conductivity type and a source region of the first conductivity type, a gate structure on the semiconductor layer structure adjacent the source region, where the gate structure includes a gate contact and a silicide blocking layer on the gate contact opposite the semiconductor layer structure, an interlayer dielectric layer on the gate structure and including an opening therein that exposes the source region, and a first conductive silicide on the source region and extending beyond edges of the opening in the interlayer dielectric layer and between interlayer dielectric layer and the semiconductor layer structure.

In some embodiments, a protective spacer may be on a sidewall of the gate structure, and the protective spacer may be directly on the semiconductor layer structure.

In some embodiments, the gate structure may include first and second gate structures on the semiconductor layer structure with the source region therebetween, the protective spacer may include first and second protective spacers on adjacent sidewalls of the first and second gate structures, respectively, and the first conductive silicide may continuously extend from the first protective spacer to the second protective spacer.

In some embodiments, the protective spacer may include a different material than the silicide blocking layer.

In some embodiments, the protective spacer may extend onto a sidewall of the silicide blocking layer, and a top portion of the gate structure opposite the semiconductor layer structure may be free of the protective spacer.

According to some embodiments, a power semiconductor device includes a semiconductor layer structure including a drift region of a first conductivity type and at least one source region of the first conductivity type, gate contacts on the semiconductor layer structure with the at least one source region therebetween, protective spacers on respective sidewalls of the gate contacts, where top portions of the gate contacts opposite the semiconductor layer structure are free of the protective spacers, an interlayer dielectric layer on the top portions of the gate contacts, and a first ohmic contact on the at least one source region and continuously extending between the protective spacers.

In some embodiments, silicide blocking layers may be between the dielectric layer and the top portions of the gate contacts.

In some embodiments, the protective spacers may include a different material than the silicide blocking layers and may extend onto side surfaces thereof.

In some embodiments, the first ohmic contact may include a first conductive silicide, and the gate contacts may be free of the first conductive silicide.

In some embodiments, second ohmic contacts may include a second conductive silicide between the dielectric layer and the top portions of the gate contacts, where the second conductive silicide is different from the first conductive silicide.

In some embodiments, the protective spacers may respectively include first and second layers of different dielectric materials.

In some embodiments, the protective spacers may be directly on the semiconductor layer structure.

According to some embodiments, a method of fabricating a semiconductor device includes providing a semiconductor layer structure including a drift region of a first conductivity type and at least one source region of the first conductivity type, providing gate contacts on the semiconductor layer structure, providing a first dielectric material on the gate contacts opposite the semiconductor layer structure as silicide blocking layers, providing a second dielectric material on respective sidewalls of the gate contacts as protective spacers, and providing a first conductive silicide on the at least one source region between the gate contacts.

In some embodiments, providing the second dielectric material may be performed before or after providing the first dielectric material.

In some embodiments, the first and second dielectric materials may be different.

In some embodiments, the first conductive silicide may continuously extend between the protective spacers on the sidewalls of the gate contacts.

In some embodiments, providing the gate contacts and the first dielectric material may include providing a gate insulating material on the semiconductor layer structure, providing a gate contact material on the gate insulating material, providing the first dielectric material on the gate contact material, and patterning the first dielectric material, the gate contact material, and the gate insulating material to form the gate contacts and silicide blocking layers thereon.

In some embodiments, providing the gate contacts and the first dielectric material may include providing a gate insulating material on the semiconductor layer structure, providing a gate contact material on the gate insulating material, patterning the gate contact material and the gate insulating material to form the gate contacts, and oxidizing the gate contacts to form the first dielectric material on the gate contacts opposite the semiconductor layer structure and on the respective sidewalls of the gate contacts, prior to providing the second dielectric material thereon.

In some embodiments, providing the second dielectric material on the respective sidewalls of the gate contacts may include performing an etchback process that forms the protective spacers directly on the semiconductor structure free of a gate insulating material therebetween.

In some embodiments, providing the first conductive silicide may include providing a first conductive layer on the at least one source region between the gate contacts after providing the first and second dielectric materials thereon, and performing a silicide reaction process on the conductive layer to form the first conductive silicide on the at least one source region such that the gate contacts are free of the first conducive silicide.

In some embodiments, the silicide reaction process is a first silicide reaction process, and the method may further include removing the silicide blocking layers after performing the first silicide reaction process, providing a second conductive layer on the gate contacts opposite the semiconductor layer structure, and performing a second silicide reaction process on the second conductive layer to form a second conductive silicide on the gate contacts, where the second conductive silicide is different from the first conductive silicide.

In some embodiments, the first silicide reaction process may be performed at a first temperature, and the second silicide reaction process may be performed at a second temperature that is lower than the first temperature.

In some embodiments, an interlayer dielectric layer may be provided on the gate contacts opposite the semiconductor layer structure after providing the first conductive silicide, and the interlayer dielectric layer may be patterned to provide at least one opening therein that exposes the at least one source region, where the first conductive silicide extends beyond edges of the at least one opening in the interlayer dielectric layer and between the interlayer dielectric layer and the semiconductor layer structure.

In some embodiments, patterning the dielectric layer may include forming a mask pattern having a plurality of openings therein on the dielectric layer, and patterning the interlayer dielectric layer based on the openings in the mask pattern to form the at least one opening therein as at least one source contact opening, and to form at least one gate contact opening therein.

According to some embodiments, a method of fabricating a semiconductor device includes providing a semiconductor layer structure including a drift region of a first conductivity type and at least one source region of the first conductivity type, providing a gate insulating material on the semiconductor layer structure, providing a gate contact material on the a gate insulating material opposite the semiconductor layer structure, providing a first dielectric material on the gate contact material opposite the gate insulating material, and patterning the first dielectric material, the gate contact material, and the gate insulating material to form gate structure including gate contacts and silicide blocking layers thereon that are spaced apart on the semiconductor layer structure with the at least one source region therebetween.

In some embodiments, a second dielectric material may be provided on respective sidewalls of the gate structures as protective spacers, and a first conductive silicide may be provided on the at least one source region between the gate structures after providing the second dielectric material thereon, where the first conductive silicide may continuously extend between the protective spacers.

In some embodiments, the protective spacers are directly on the semiconductor layer structure free of the gate insulating material therebetween.

In some embodiments, the first and second dielectric materials may be different, and the second dielectric material may extend onto the first dielectric material.

In some embodiments, providing the first conductive silicide may include providing a first conductive layer on the at least one source region between the gate contacts after providing the first and second dielectric materials thereon, and performing a silicide reaction process on the conductive layer to form the first conductive silicide on the at least one source region such that the gate contacts are free of the first conducive silicide.

In any embodiments, the semiconductor layer structure may include a wide bandgap semiconductor material.

Other devices, apparatus, and/or methods according to some embodiments will become apparent to one with skill in the art upon review of the following drawings and detailed description. It is intended that all such additional embodiments, in addition to any and all combinations of the above embodiments, be included within this description, be within the scope of the invention, and be protected by the accompanying claims.

### BRIEF DESCRIPTION OF THE DRAWINGS

FIGS. 1A and 1B are schematic cross-sectional views illustrating example power semiconductor devices having planar and trenched transistor structures, respectively, with self-aligned ohmic silicided source contacts according to some embodiments of the present disclosure.

FIG. 1C is a schematic cross-sectional view illustrating an example power semiconductor device having a planar transistor structure with self-aligned ohmic silicided source contacts and silicided gate contacts according to some embodiments of the present disclosure.

FIGS. 2A and 2B are schematic cross-sectional views illustrating example power semiconductor devices having planar and trenched transistor structures, respectively, with self-aligned ohmic silicided source contacts according to further embodiments of the present disclosure.

FIG. 2C is a schematic cross-sectional view illustrating an example power semiconductor device having a planar transistor structure with self-aligned ohmic silicided source contacts and silicided gate contacts according to further embodiments of the present disclosure.

FIGS. 3A, 3B, 3C, 3D, 3E, and 3F are schematic cross-sectional views illustrating intermediate fabrication operations in methods of fabricating power semiconductor devices with self-aligned ohmic silicided source contacts according to some embodiments of the present disclosure.

FIGS. 4A, 4B, 4C, 4D, 4E, and 4F are schematic cross-sectional views illustrating intermediate fabrication operations in methods of fabricating power semiconductor devices with self-aligned ohmic silicided source contacts according to further embodiments of the present disclosure.

FIGS. 5A, 5B, 5C, 5D, 5E, and 5F are schematic cross-sectional views illustrating intermediate fabrication operations in methods of fabricating power semiconductor devices with self-aligned ohmic silicided source contacts according to further embodiments of the present disclosure.

FIGS. 6A, 6B, 6C, 6D, 6E, and 6F are schematic cross-sectional views illustrating intermediate fabrication operations in methods of fabricating power semiconductor devices with self-aligned ohmic silicided source contacts according to further embodiments of the present disclosure.

### DETAILED DESCRIPTION OF EMBODIMENTS

Vertical power semiconductor devices that include a MOSFET transistor may be implemented using several different wide bandgap (WBG) semiconductor structures. For example, a planar MOSFET structure may include a standard gate electrode design in which the gate electrode of the transistor is formed on top of the semiconductor layer structure. A trench MOSFET structure may include the gate electrode buried in a trench within the semiconductor layer structure, and may also be referred to as a gate trench MOSFET. These vertical power semiconductor device structures utilize a p-n junction barrier and the inversion of a doped well region to provide electron flow from source to drain in a vertical direction. Although described and illustrated herein with reference to regions of specific conductivity types (i.e., n-type and p-type) by way of example, it will be understood that the conductivity types of the regions in any of the illustrated examples may be reversed (i.e., p-type and n-type) in accordance with embodiments of the present invention.

Embodiments of the present disclosure are directed to power semiconductor devices including ohmic contact regions, which may be implemented by conductive silicides, with low resistivity and large ohmic area. However, typical methods for forming self-aligned silicides in a planar silicon-based technology may not be applicable to a wide-bandgap technology like planar SiC, because silicide materials that may form a good ohmic contact on SiC may not be optimal for simultaneously forming a silicide on polysilicon elements, such as the gate electrodes. In particular, in a planar silicon device, it may be common to simultaneously form a silicide both on source/well/drain regions and on the polysilicon gate using a silicide material such as Ti, Co, etc. However, some preferred silicide materials for forming a good ohmic contact on SiC, such as Ni, may be a poor choice for siliciding a polysilicon gate, due to the propensity of the material to absorb polysilicon grains and migrate through those grains, which may eventually compromise gate oxide integrity.

Some embodiments of the present disclosure may arise from realization that, in wide-bandgap power semiconductor devices including ohmic contacts, it may be desirable to avoid silicidation of the polysilicon gate with wide bandgap silicidation materials, which may typically damage the structure of the polysilicon and the underlying gate oxide. Embodiments of the present disclosure thus provide methods and devices that may increase the surface area of ohmic contacts (and thus, reduce specific resistance Rsp) for wide-bandgap power devices, by using self-aligned techniques that can prevent silicidation of polysilicon (or other gate materials) by WBG-specific silicide materials, so as to increase or maximize area of the WBG ohmic contact regions for various power semiconductor device cell architectures.

Particular embodiments of the present disclosure may utilize self-aligned techniques that cover the top and edges of a polysilicon gate (or other gate) by one or more non-reactive encapsulating materials (e.g., using silicide blocking layers and/or gate protective spacers formed of an insulator such as SiO₂ (including TEOS), SiN, or SiON, which do not react to form silicides) to prevent silicidation of the gate during the thermal cycles that are used to create the WBG silicide-based ohmic contacts (also referred to herein as WBG ohmic contact regions) on the source/well regions in a planar device structure. The WBG ohmic contact regions may be self-aligned to the gates based on protective spacers formed on sidewalls of the gate structures. That is, particular embodiments of the present disclosure include a WBG silicide blocking layer on top of a polysilicon gate, protective spacers on sidewalls of the gate and extending up to the silicide blocking layer or beyond (e.g., along sidewalls of the silicide blocking layer), and/or other encapsulation of the polysilicon-based gates before silicidation of the WBG semiconductor surfaces.

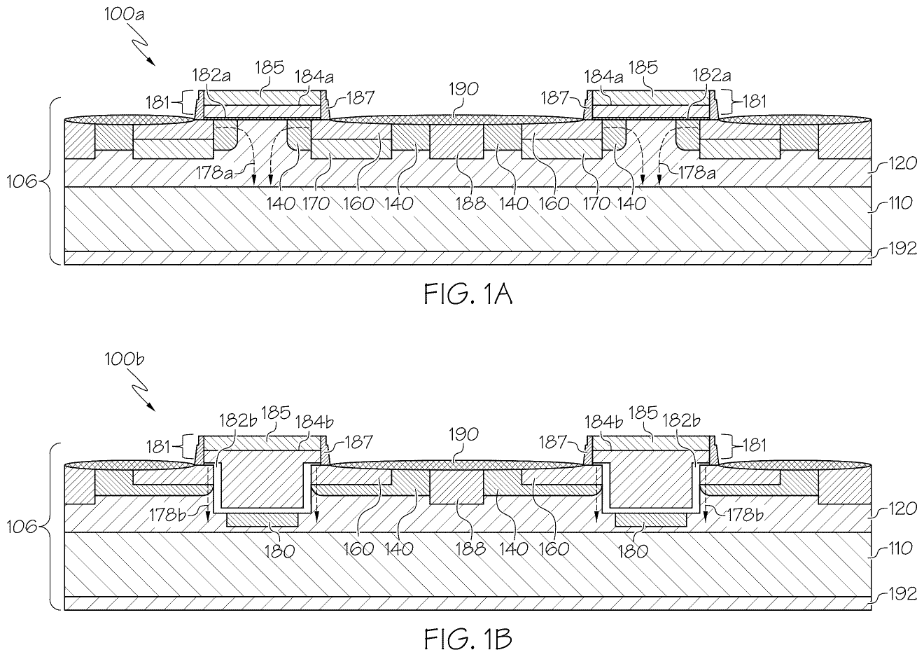

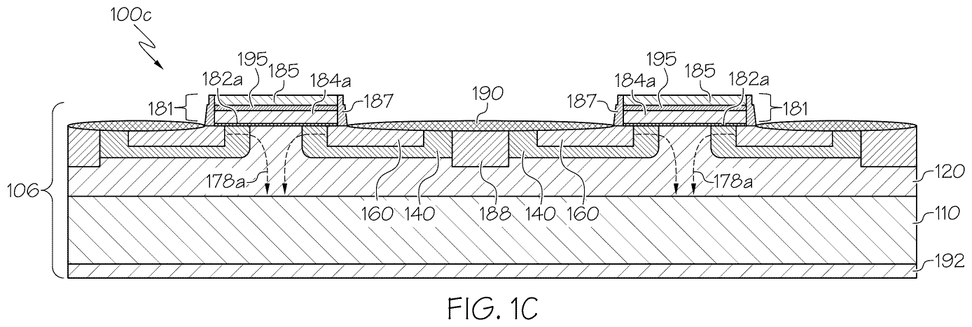

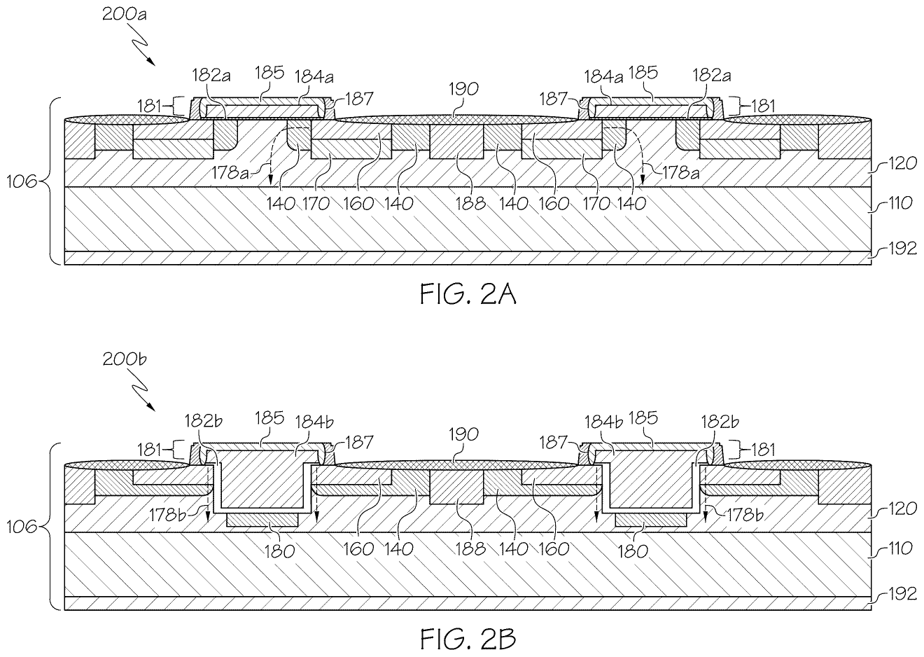

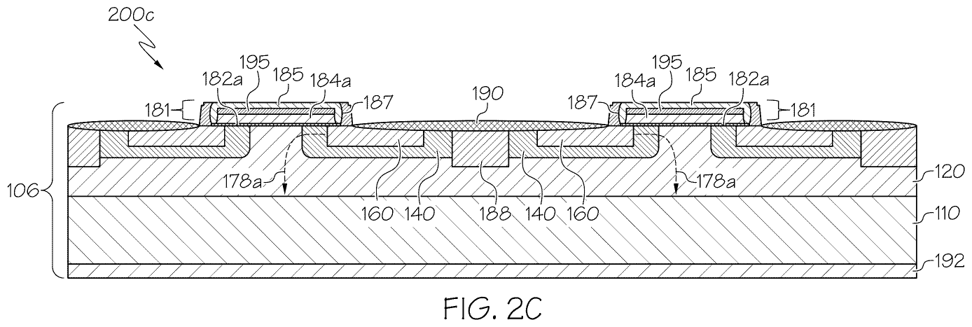

FIGS. 1A, 1B, 2A, and 2B are schematic cross-sectional views illustrating example power semiconductor devices with self-aligned ohmic silicided source contacts according to some embodiments of the present disclosure, illustrated as partial unit cells of planar MOSFETs 100a, 200a, or trench MOSFETs 100b, 200b. FIGS. 1C and 2C are schematic cross-sectional views illustrating example power semiconductor devices with self-aligned ohmic silicided source contacts and silicided gate contacts, illustrated as partial unit cells of a planar MOSFET 100c. It will be understood that the unit cells 100a, 100b, 100c may be replicated in one or more dimensions to define a power semiconductor device as described herein.

As shown in FIGS. 1A to 1C and 2A to 2C, the power MOSFETs 100a, 100b, 100c (collectively 100) and 200a, 200b, 200c (collectively 200) each include a substrate 110 of a first conductivity type (e.g., n-type) formed from a wide bandgap semiconductor material, for example, silicon carbide. The substrate 110 may define a drain region for the devices 100, and a drain contact 192 may be provided thereon. A drift layer or region 120 of the first conductivity type is provided on the substrate 110, for example, by epitaxial growth. The drift region 120 may be doped with impurities of the first conductivity type (e.g., nitrogen (N) or phosphorous (P) for an n-type drift region), and may have a dopant concentration of about 5×10¹⁴ to 5×10¹⁷ atoms/cm³, for example, about 5×10¹⁵ to 5×10¹⁶, about 8×10¹⁵ to 2×10¹⁶ atoms/cm³, or about 9×10¹⁵ to 1×10¹⁶ atoms/cm³. For example, the substrate 110 may be a n-type (e.g., n⁺) silicon carbide substrate, and a lightly-doped (e.g., n⁻) n-type drift layer or region 120 may be epitaxially grown on the substrate 110. In some embodiments, a portion of the drift region 120 may include a current spreading layer (“CSL”) of the first conductivity type and having a higher doping or dopant concentration than the drift region 120.

Moderately-or heavily-doped regions of a second conductivity type (e.g., p-type) are formed (for example, by epitaxial growth or implantation) on the drift region 120 and act as base or well regions (or “wells”) 140, 170 for the devices 100. Simplified well regions (omitting the heavily-doped regions 170) are shown by way of example in FIGS. 1B, 1C, 2B, and 2C (but may be utilized in any of the embodiments described herein). A heavily-doped base or well contact region 188 of the second conductivity type (e.g., p+) is formed adjacent the well regions 140. The p-n junction between the second conductivity type well contact region 188 and the first conductivity type drift region 120 may define a diode in the semiconductor layer structure 106, also referred to herein as a body diode.

Heavily-doped source regions 160 of the first conductivity type (e.g., n+) are formed in upper portions of the well regions 140, 170, for example, via ion implantation. The source region 160 may be doped with n-type impurities, and may have a dopant concentration of about 5×10¹⁸ to 5×10²¹ atoms/cm³, for example, about 8×10¹⁸ to 1×10²¹ atoms/cm³, about 1×10¹⁹ to 5×10²⁰ atoms/cm³, or about 5×10¹⁹ to 1×10²⁰ atoms/cm³. That is, the source region 160 has a dopant concentration that is greater than the dopant concentration of the drift region 120, e.g., by a factor of about 10 or more in some embodiments. The substrate 110, drift region 120 (including current spreading layer), well regions 140, 170, well contact regions 188, and source regions 160, along with various regions/patterns formed therein, are included in the silicon carbide (or other wide bandgap semiconductor) layer structure 106.

A gate insulating layer, for example oxide layer 182a, 182b (collectively 182), is formed on portions of the drift region 120, the well regions 140, 170, and the source regions 160. A gate contact (or “gate”) 184a, 184b (collectively 184) is formed on the gate oxide layer 182. The gate insulating layer 182 and the gate 184 thereon may be collectively referred to herein as the gate structure 181.

More particularly, in the planar MOSFETs 100a, 100c, 200a, and 200c of FIGS. 1A, 1C, 2A, and 2C, the gate oxide layer 182 a is formed on portions of the drift region 120, the well regions 140, and the source regions 160 adjacent a surface of the semiconductor layer structure 106, and the gate 184a is formed on the gate oxide layer 182a extending along the surface of the structure 106. A transistor channel region 178a for each planar MOSFET 100a, 100c unit cell (with conduction shown by dashed arrows) is defined through the wells 140 and the portions of the drift region 120 underneath the gate 184a. For example, the inversion channel 178a of planar SiC MOSFET may be on the Si-face of SiC.

In the trench MOSFETs 100b and 200b of FIGS. 1B and 2B, a gate trench is formed extending from the surface of the semiconductor layer structure 106 into the drift region 120, the gate oxide layer 182b is formed on sidewalls and a bottom surface of the gate trench, and the gate 184b is formed on the gate oxide layer 182a to fill the gate trench. Transistor channel regions 178b for each trench MOSFET 100b, 200b unit cell (with conduction shown by dashed arrows) are defined vertically through the wells 140 (which may be more moderately doped in FIGS. 1B and 2B, as compared to FIGS. 1A and 2A) along sidewalls of the gate trench. For example, the inversion channel 178b of a trench SiC MOSFET may be along the sidewalls of the trench, on the a-face or the m-face of SiC. The trench MOSFETs 100b, 200b further include shielding patterns 180 underneath the gate trench in order to reduce the electric field levels in the gate insulating layer 182b, particularly at corners of the gate trenches where the electric field levels may be more concentrated. The shielding patterns 180 may include doped semiconductor layers having the same conductivity type (in this example, p-type) as the well regions 140, 170, but having a greater dopant concentration (e.g., p+) than the well regions 140, 170.

As described herein, embodiments of the present invention may allow for fabrication of self-aligned ohmic contacts to the semiconductor layer structure 160, and in some embodiments ohmic gate contacts, with desired or optimized materials and/or characteristics. As shown in FIGS. 1A to 1C and 2A to 2C, the power MOSFETs 100, 200 each include ohmic contacts 190 on source regions 160 and well contact regions 188. The ohmic contacts 190 may laterally extend beyond the source regions 160 and well contact regions 188 and onto adjacent well regions 140 in some embodiments.

An ohmic contact may refer to a non-rectifying electrical junction between two conductors (e.g., a metal and a semiconductor) that has a linear current-voltage (I-V) curve. Suitable metals for forming ohmic contacts may include refractory metals, such as Ti, W, titanium tungsten (TiW), silicon (Si), titanium tungsten nitride (TiWN), tungsten silicide (WSi), rhenium (Re), Niobium (Nb), Ni, gold (Au), aluminum (Al), tantalum (Ta), molybdenum (Mo), NiSiₓ, titanium silicide (TiSi), titanium nitride (TiN), WSiN, Pt and the like. However, as noted above, some preferred silicide materials for forming a good ohmic contact to wide bandgap semiconductor materials (such as Ni) may have a propensity to absorb and migrate through polysilicon grains, and thus may be a poor choice for siliciding a polysilicon gate.

In embodiments of the present disclosure, the ohmic contacts 190 may be formed of a conductive silicide (such as NiSi) that is selected or otherwise configured to provide good ohmic contact to the wide bandgap semiconductor materials (such as SiC) of the source regions 160 and well contact regions 188, also referred to herein as a WBG silicide. Thus, the ohmic contacts 190 may include a conductive silicide in direct contact with the epitaxial layer 120, or more generally, with the semiconductor layer structure 106. In some embodiments, the ohmic contacts 190 may be formed of a plurality of layers or metals.

For example, for a SiC semiconductor layer structure 106, a first metal or metal compounds may be formed on the source regions 160 and well contact regions 188, and may be silicided (e.g., using anneal processes, as described below) to form the ohmic contacts 190 of first conductive silicide with desired characteristics. In some embodiments, the ohmic contacts 190 may have a contact resistance of less than about 5×10⁻³ ohm-cm², e.g., less than about 1×10⁻³ ohm-cm² or less than about 1×10⁻⁴ ohm-cm². In some embodiments, the ohmic contacts 190 may have one or more dimensions that are smaller than the CD for some conventional patterning processes. For example, the contacts 190 may have at least one dimension in plan view (e.g., along a length or width direction) of less than about 2 μm, for instance, about 2 μm to about 1 μm, or about 1.75 μm to about 1.25 μm, e.g., about 1.5 μm or about 1 μm in some embodiments.

Still referring to FIGS. 1A to 1C and 2A to 2C, silicide blocking layers 185 are provided on the gate contacts 184 opposite the semiconductor layer structure 106 (i.e., on “top” of the gates 184), and protective spacers 187 (e.g., SiN, SiON, or SiO₂) are provided on at least one sidewall 181s of the gate structures 181, to prevent silicidation of the gates 184 during silicidation processes to form ohmic contacts 190 on the source regions 160 and/or well contact regions 188 described below. The gate structures 181 of FIGS. 1A, 1B, 2A, and 2B thus include a stack of two or more layers, for example, a gate contact 184 and a silicide blocking layer 185. The protective spacers 187 extend directly onto the semiconductor layer structure 106, so as to prevent silicidation of the sidewalls 181s of the gate structure 181 (and in particular, to prevent migration of silicides from the ohmic contacts 190 to the gate sidewalls 184s). The protective spacers 187 thus define respective interfaces with the semiconductor layer structure 106, free of the gate insulating layers 182 therebetween. The silicide blocking layers 185 and the protective spacers 187 may be formed of different materials (e.g. an oxide and a nitride, respectively) or may be formed of the same materials, in various embodiments described herein, and may allow for forming self-aligned ohmic contacts 190 as described herein.

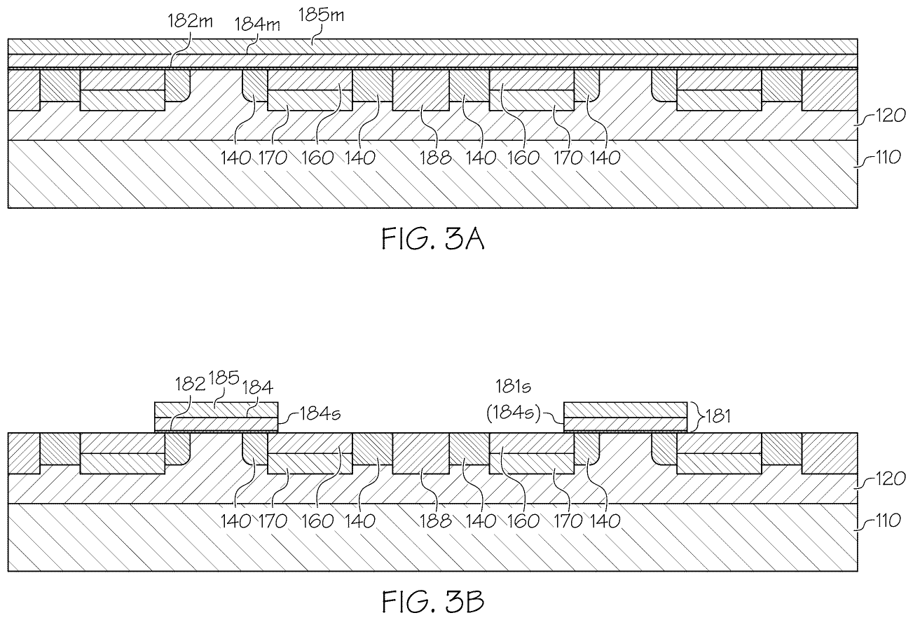

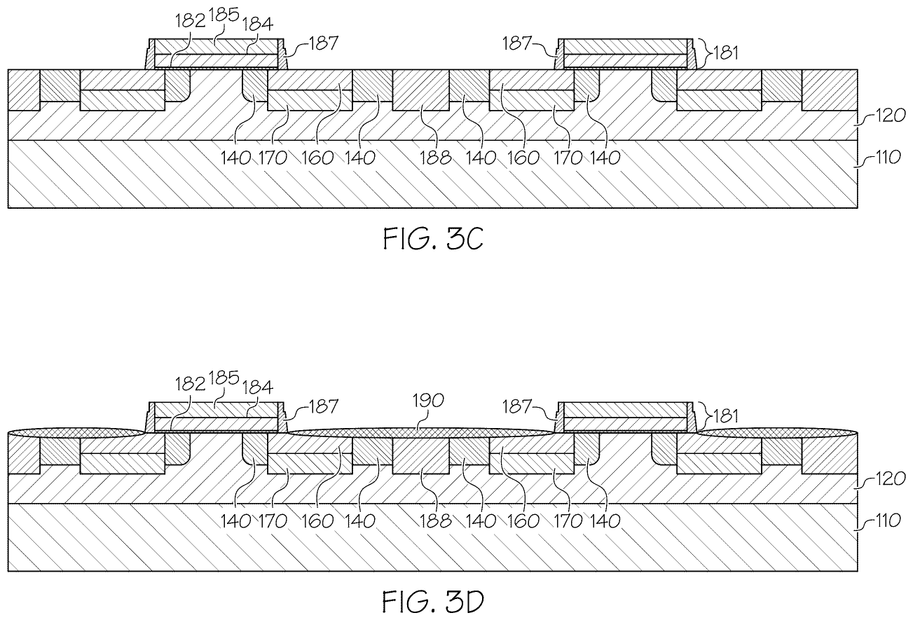

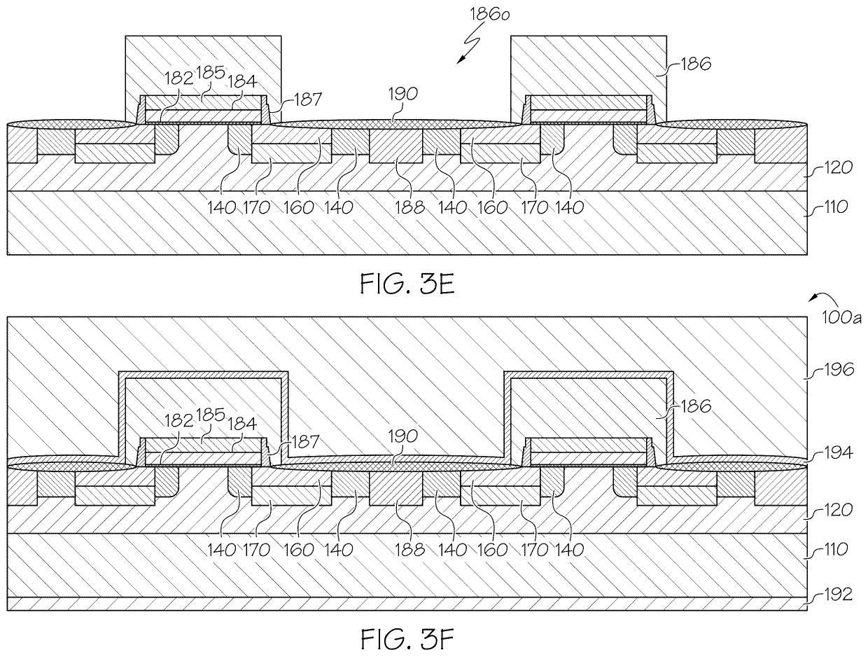

FIGS. 1A to 1C illustrate power MOSFETs 100 in which the silicide blocking layers 185 are formed before patterning of the gates 184, such that the silicide blocking layers 185 do not extend on sidewalls 184s of the gates 184. Example fabrication operations for forming the power MOSFET 100a of FIG. 1A are shown below in FIGS. 3A to 3F.

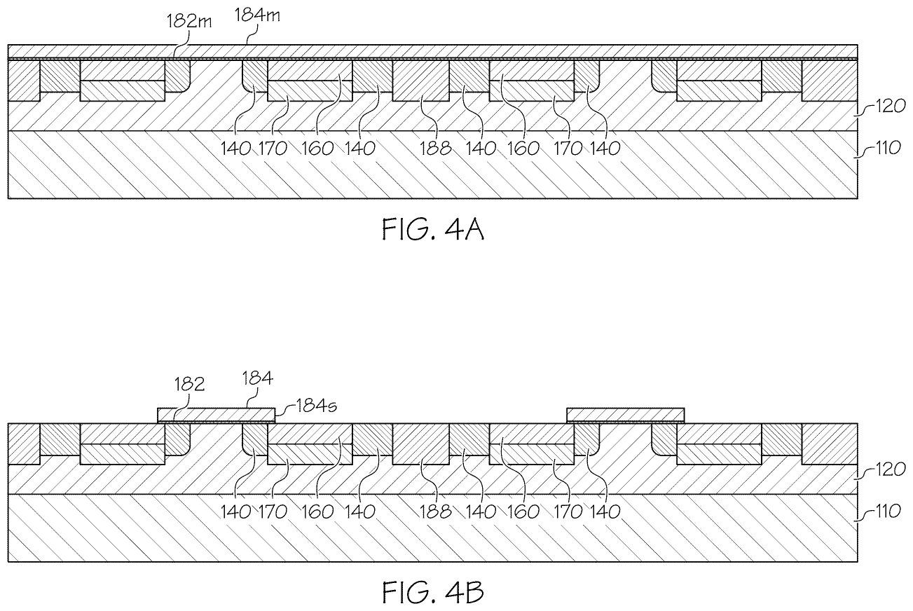

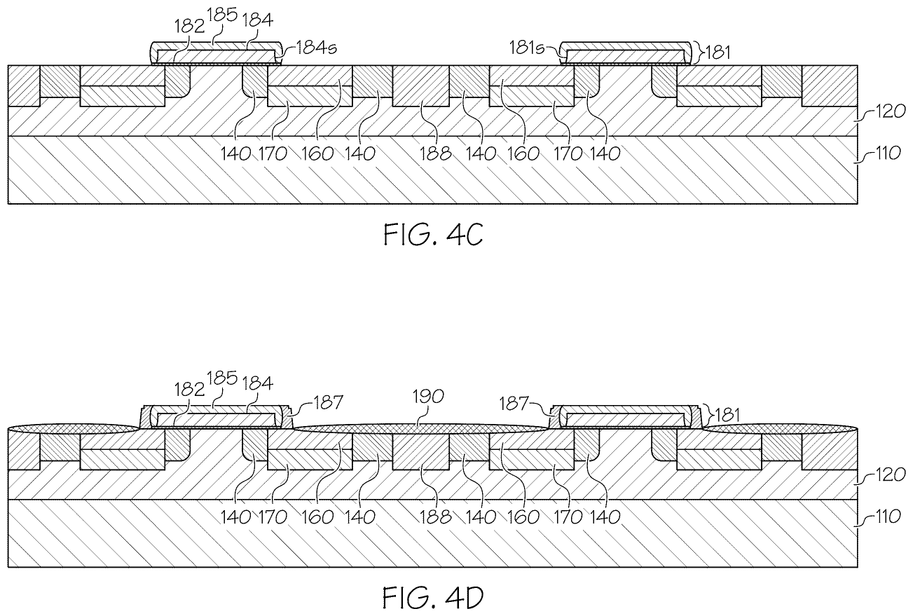

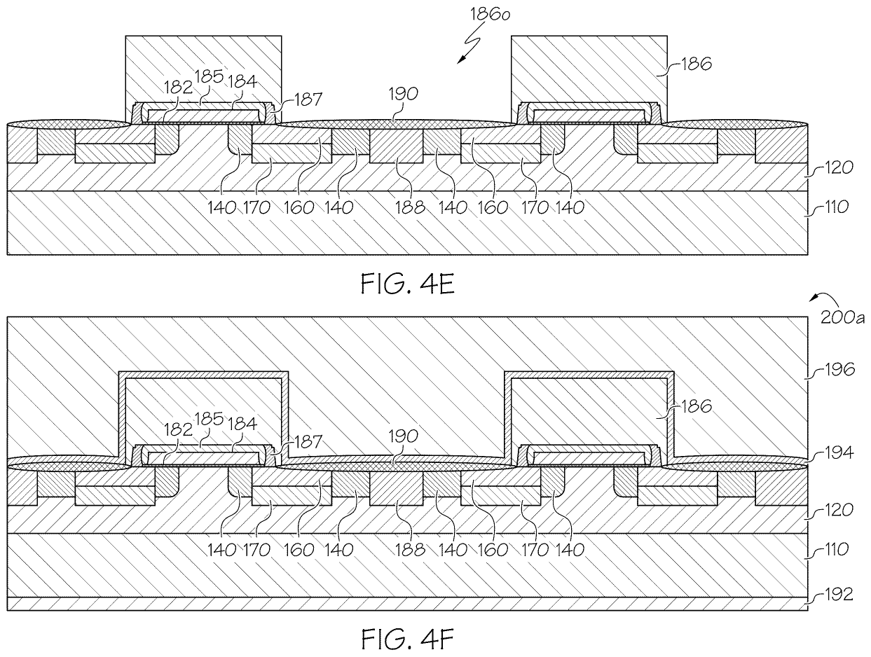

FIGS. 2A to 2C illustrate power MOSFETs 200 in which the silicide blocking layers 185 are formed after patterning of the gates 184, such that the silicide blocking layers 185 extend on sidewalls 184s of the gates 184 and between the gates 184 and the protective spacers 187. Example fabrication operations for forming the power MOSFET 200a of FIG. 2A are shown below in FIGS. 4A to 4F.

Further embodiments described herein may allow for metal(s), temperature(s) and/or other fabrication conditions to be independently selected so as to optimize resistance, current distribution, and/or other characteristics of self-aligned ohmic contacts 190, without degrading or otherwise negatively affecting the remaining contacts or other features. In particular, gate ohmic contacts 195 may be formed of a different conductive silicide (such as TaSi, WSi, or TiSi) that is selected or otherwise configured to provide good ohmic contact to the gates 184a. That is, a second metal or metal compound, different than the first metals/compounds, may be formed on the gates 184a and may be silicided to form second conductive silicide-based gate ohmic contacts 195 with desired characteristics.

For example, as shown in the power MOSFETs 100c and 200c of FIGS. 1C and 2C, the gates 184a may be pre-silicided (e.g., using a high-temperature silicide process) to form the gate ohmic contacts 195 before formation of the silicide blocking layers 185. The high-temperature silicide-based ohmic contacts 195 may be formed from materials (e.g., TaSi or WSi) that may withstand higher-temperature WBG silicidation operations (e.g., at annealing temperatures of greater than 900° C., such as 950° C.) that may be subsequently used to form the ohmic contacts 190 to the source 160 and well contact 188 regions. As such, in the example of FIG. 1C, the gate structure 181 may include a stack of three or more layers, in particular, the gate contact 184a, the conductive silicide-based gate ohmic contact 195, and the silicide blocking layer 185.

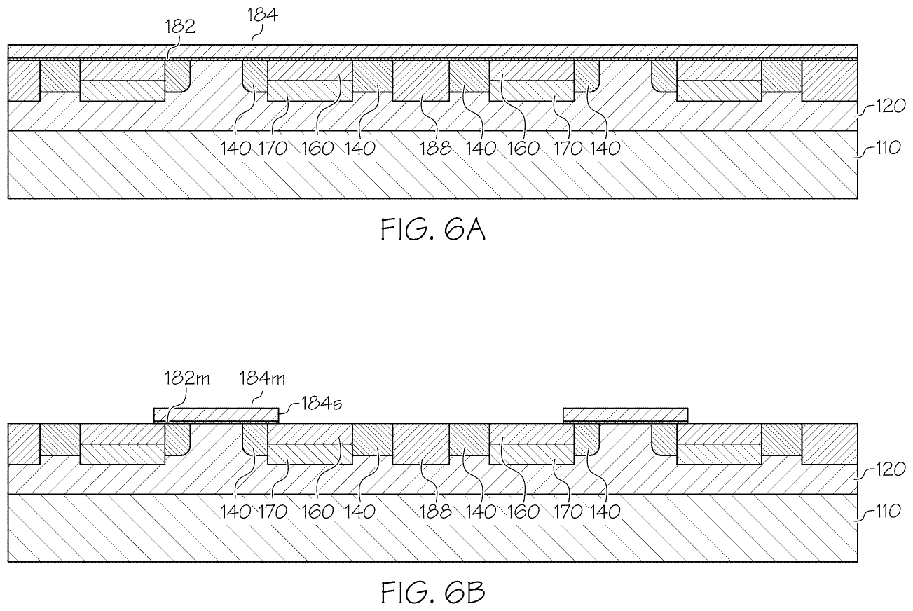

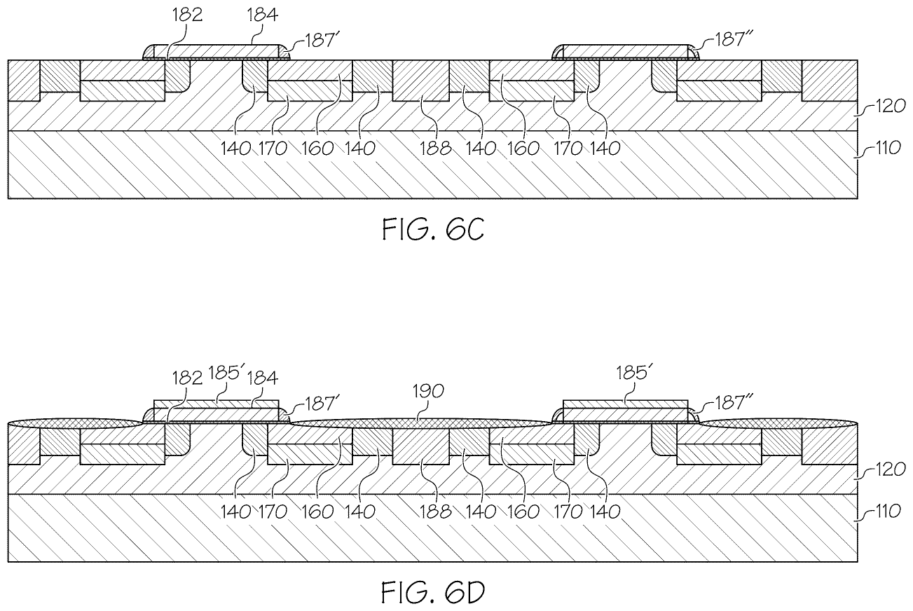

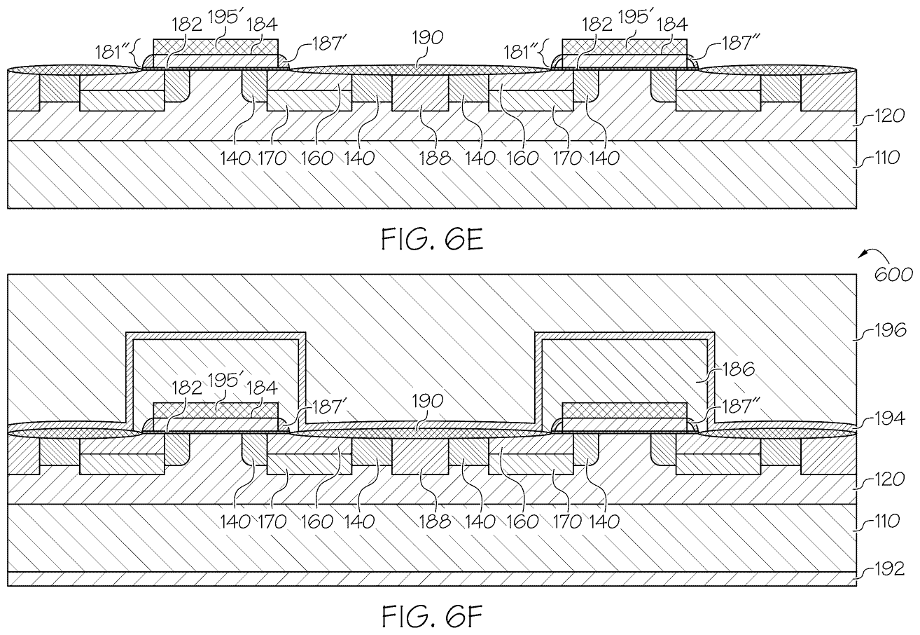

Alternatively, as shown in the power MOSFET 600 of FIG. 6F, the gates 184 may be post-silicided (e.g., using a low-temperature silicide process) to form the gate ohmic contacts 195′ after forming the silicide blocking layers 185 and performing higher-temperature WBG silicidation operations to form the ohmic contacts 190 to the source 160 and well contact 188 regions. In particular, after forming the ohmic contacts 190, the silicide blocking layers 185 may be removed, and a low-temperature silicide-based ohmic contacts 195′ (at annealing temperatures of about 850° C.or below, such as 800° C.) may be formed on the gates 184. The low-temperature silicide-based gate ohmic contacts 195′ may be formed from materials (such as TiSi) that may provide lower resistance than TaSi or WSi. That is, because the higher temperature silicides for the WBG ohmic contacts 190 were formed in previous processes, the metal(s) and/or fabrication conditions (including anneal temperature(s)) for the gate ohmic contacts 195 can be independently selected so as to optimize resistance, current distribution, and/or other characteristics.

As described in greater detail below with reference to the fabrication operations shown in FIGS. 3A to 6F, one or more interlevel dielectric layers 186, such as intermetal dielectric (IMD) layer(s) (more generally referred to herein as interlayer dielectric (ILD) layer(s)), are formed on a surface of the semiconductor layer structure 106 including the ohmic contacts 190 and the gate contacts 184. The dielectric layer(s) 186 may differ from final passivation layers in materials, thicknesses, and/or functionality. For example, the dielectric layer(s) may be configured to insulate the gate contacts 184 (with or without the silicide blocking layers 185 thereon) and the ohmic contacts 190 from subsequent interconnect layers, such as the metal contact layer(s) 196 described below. A drain contact 192 may be formed on the lower surface of the substrate 110, opposite to the dielectric layer(s) 186.

In some embodiments, as shown in FIGS. 3F, 4F, 5F, and 6F, the dielectric layer(s) 186 laterally extend onto edges of the first ohmic contacts 190, for instance, adjacent the gate contacts 184. For example, the first ohmic contact 190 may be formed before formation of the interlayer dielectric layer(s) 186. As such, the ohmic contacts 190 may extend fully or continuously from one spacer 187 to an adjacent spacer 187, i.e., under and beyond openings 186o in the ILD 186, thereby improving current distribution. That is, the ohmic contacts 190 may not be confined only to areas of the semiconductor structure 106 that are exposed by openings 186o in the ILD 186 (in contrast to some conventional devices, in which the conductive silicide may be deposited directly into the contact openings 186o after deposition of the ILD 186). In addition, because the silicidation of the semiconductor surfaces 106 is performed before formation of the ILD 186, the ILD 186 may be patterned using the same mask to form openings for both the source contacts and the gate contacts, thereby reducing the number of masking operations that may be required in the fabrication process.

FIGS. 3A to 3F are schematic cross-sectional views illustrating intermediate fabrication operations in methods of fabricating power semiconductor devices with self-aligned ohmic silicided source contacts according to some embodiments of the present disclosure.

As shown in FIG. 3A, a semiconductor layer structure 106 including a drift region 120 of a first conductivity type, base/well regions 140/170 of a second conductivity type, source regions 160 of the first conductivity type, and base/well contact regions 188 of the second conductivity type are provided on a substrate 110. A gate insulating material 182m is formed or otherwise provided on the semiconductor layer structure 106, a gate contact material 184m is formed or otherwise provided on the a gate insulating material 182m opposite the semiconductor layer structure 106, and a first dielectric material 185m is formed or otherwise provided on the gate contact material 184m opposite the gate insulating material 182. The gate insulating material 182m may be an oxide material, the gate contact material 184m may be polysilicon or other conductive material, and the first dielectric material 185m may be an oxide, nitride, oxynitride, or other dielectric material in some embodiments.

More particularly, after the gate contact material 184m is deposited and doped (but before patterning and etching), the first dielectric material 185m is formed on a top surface of the polysilicon layer 184m (e.g., by deposition or oxidation). The first dielectric material 185m functions to prevent silicide formation on the gate contacts 184 during subsequent silicidation processes for forming ohmic contacts 190 on the wide-bandgap semiconductor layer structure 106.

As shown in FIG. 3B, the first dielectric material 185m, the gate contact material 184m, and the gate insulating material 182m are patterned to form gate insulating layers 182, gate contacts 184, and silicide blocking layers 185 thereon. For example, the first dielectric material 185m, the gate contact material 184m, and the gate insulating material 182m may be patterned and etched together as a stack. The first dielectric material 185m of the silicide blocking layers 185 can be any material which is selected or otherwise configured to prevent silicidation of the gate contacts 184, including silicon oxides, silicon nitrides, or silicon oxynitrides that may block the WBG conductive silicide 190 from migrating to the gates 184. If oxidation (rather than deposition) is used to form the silicide blocking layer 185, the silicide blocking layer 185 may be a silicon dioxide film.

The gate insulating layers 182, gate contacts 184, and silicide blocking layers 185 provide gate stacks or structures 181 that are laterally spaced apart on the semiconductor layer structure 106 with the source region(s) 160 therebetween. The patterning process shown in FIG. 3B defines sidewalls 181s of the gate structure 181 (and thus, sidewalls 184s of the gate contacts 184). In some embodiments, the gate structures 181 may further include a silicide-based gate ohmic contacts 195 (e.g., as shown in FIG. 1C) in the stack 181, between the gate contact 184 and the silicide blocking layer 185. For example, gate ohmic contacts 195 may be a polysilicon-friendly high-temperature silicide (such as TaSiₓ, WSiₓ, which may also function to prevent silicidation of the gate contacts 184a by the conductive silicide materials used to form the ohmic contacts 190) or a low-temperature silicide (such as TiSiₓ). That is, the gate structures 181 may be a multi-layer stack including the silicide blocking layer 185 (such as oxides or nitrides that block silicidation), the gate contact 184 (such as a bottom polysilicon film), the gate insulating layer 182, and in some embodiments, silicide-based gate ohmic contacts 195 (such as TaSiₓ or WSiₓ or TiSiₓ). The gate ohmic contacts 195 may be effectively encapsulated within the gate stack 181 by the protective spacers 187, so as to prevent migration between the silicided metal of the WBG ohmic contacts 190 (e.g., Ni) and the silicided metal of the gate ohmic contacts 195 (e.g. Ti).

In FIG. 3B, the top surfaces of the gate contacts 184 are protected from silicidation by subsequent silicidation processes, but the sidewalls 184s of the gate contacts 184a are not protected. As shown in FIG. 3C, a second dielectric material is provided on respective sidewalls 181s of the gate structures 181 (and in particular, on sidewalls 184s of the gates 184) and patterned to form protective spacers 187. That is, the protective spacers 187 may be formed after the silicide blocking layers 185. The protective spacers 187 may be formed of silicon oxides, including TEOS oxides, silicon nitrides, and silicon oxynitrides.

The protective spacers 187 may be self-aligned to the sidewalls 181s of the gate structures 181. In particular, one or more second dielectric films may be formed on the surface of the semiconductor layer structure 106 having the gate stacks or structures 181 laterally spaced apart thereon, and the deposited film(s) may be anisotropically etched to form self-aligned spacers 187 on the sidewalls 181s of the gate structures 181 including the silicide blocking layer 185/gate contact 184/gate insulating layer 182 stack. The spacer film etchback process may leave surfaces of the semiconductor layer structure 106 exposed, while covering side surfaces and edges of the gate contacts 184 by the protective spacers 187.

The protective spacers 187 are formed directly on the semiconductor layer structure 106, free of the gate insulating material 182 therebetween, and may have a width, thickness, or other dimension(s) sufficient to prevent migration of the conductive silicides of the ohmic contacts 190 to the gates 184. For example, the deposited thickness of the spacer film and the etchback process are configured to ensure that the spacers 187 are tall enough to completely cover the sidewalls 184s of the gate contacts 184. In some embodiments, the protective spacers 187 may further extend onto the side surfaces of the silicide blocking layers 185, to provide further encapsulation of the gate contacts 184. In addition, the deposited thickness of the spacer film and the etchback process are also configured to ensure that the spacers 187 are wide enough to provide dielectric isolation from the edge of the WBG conductive silicide 190 (which will be at source potential) to the edge of the polysilicon gate (which will be at gate potential). That is, protective spacers 187 as described herein extend from sidewalls of the gate contacts 184 and directly onto the surface of the semiconductor layer structure 106 (free of the gate insulating layer 182 therebetween), such that the interface therebetween provides a seal at the bottom corners of the gate contacts 184 and gate insulating layers 182 that is sufficient to prevent electrical contact between the gate structure 181 and a conductive silicide 190 formed as an ohmic contact to the source region 160 (e.g., due to migration of the conductive silicide 190).

As such, the sidewalls 184s of the gate contacts 184 are covered by the protective spacers 187, while the top surfaces of the gate contacts 184 are covered by the silicide blocking layers 185. In some embodiments, the dielectric materials of the silicide blocking layers 185 and the protective spacers 187 may be different. For example, the protective spacers 187 may be formed of materials (e.g., SiN or other nitride-based materials) to provide etch-selectivity to the silicide blocking layer 185 and/or ILD 186 layers described herein (e.g., SiO or other oxide-based materials).

As shown in FIG. 3D, a conductive silicide 190 is formed on the source region(s) 160, the well regions 140, and/or the well contact regions 188 of the semiconductor layer structure 106 between adjacent gate structures 181. For example, a first conductive layer may be formed on at least one source region 160 between the gate contacts 184 after forming the silicide blocking layers 185 and the protective spacers 187 thereon, and at least one silicide reaction process may be performed on the first conductive layer to form the conductive silicide 190 on the at least one source region(s) 160, well regions 170, and/or well contact regions 188, such that the gate contacts 184 are free of the conductive silicide 190. In particular, a first metal (such as Ni or other metal(s) that provide low resistance to WBG materials) may be formed on surfaces of the semiconductor layer structure 106 exposed by the gate structures 181, a first silicide reaction anneal (e.g., a first rapid temperature anneal RTA1) may be performed, a wet etching process may be performed to remove unreacted portions of the WBG silicide metal, and a second silicide reaction anneal (e.g., a second rapid temperature anneal RTA2) may be performed to convert the conductive silicide into a low-resistance form (e.g., NiSi) to provide the ohmic contacts 190. As such, the low-resistance conductive silicide 190 may continuously extend between adjacent protective spacers 187 on the surface of the semiconductor layer structure 106 (e.g., on up to the entire active area). The conductive silicide 190 is thereby formed in a self-aligned manner using the protective spacers 187, without the use of additional masking operations.

As shown in FIG. 3E, one or more dielectric or ILD layers 186 are formed on the surface of the semiconductor layer structure 106 (covering the ohmic contacts 190 and the gate structures 181) and are patterned to define contact openings 186o that expose the ohmic contacts 190. As the operations to form the ohmic contacts 190 were performed before deposition of the ILD layer(s) 186, portions of the ILD layer(s) 186 are provided on the gate structures 181 and laterally extend onto edges of the ohmic contacts 190 adjacent the gate structures 181. That is, the ohmic contacts 190 may extend beyond edges of the openings 186o in the ILD layer(s) 186, such that the contact opening 186o in the ILD layer(s) 186 may not completely expose the ohmic contacts 190.

Also, the ILD 186 may be patterned using a same mask to form not only the contact openings 186o that expose the ohmic contacts 190 to the source regions 160, but also additional openings (not shown in the cross-section of FIG. 3E) that expose areas for forming conductive gate pads (which are electrically connected to the gate contacts 184). That is, patterning the dielectric layer may include forming a mask pattern having a plurality of openings therein, and patterning the interlayer dielectric layer 186 based on the openings in the mask pattern to form the source contact openings 186o, and to form at least one gate contact opening therein. In other words, the same mask and patterning operations may be used to form gate pad openings and source contact openings 186o in the ILD layer(s) 186, thereby reducing the number of masking operations that may be required in the fabrication process.

FIG. 3F illustrates barrier and contact metal deposition in the source contact opening 186o (as well as in gate pad openings in some embodiments). As shown in FIG. 3F, one or more barrier metal layers 194 (e.g., Ti, Al, TiN, Ta, or TaN) may be conformally formed in the contact opening 186o and on surfaces of the ILD layer(s) 186 outside the contact opening 186o. One or more contact metal layer(s) 196 (e.g., Al, Ti, tantalum (Ta), or tungsten (W)) are formed on the barrier metal layer(s) 194 to substantially fill the contact opening 186o. For example, the metal layer(s) 196 may be aluminum (e.g., formed using a hot Al deposition) and/or tungsten (for example, formed using chemical vapor deposition), e.g., with a thicker Al sublayer on a W plug. Due to the lateral extension of the ILD layer(s) 186 onto edges of the ohmic contacts 190, the contact metal layer(s) 196 may contact less than an entirety of the ohmic contacts 190.

The drain contact 192 is also formed (e.g., on a surface of the substrate 110 opposite to the drift region 120), thereby completing the device 100a of FIG. 1A. However, it will be understood that some the operations described in FIGS. 3A-3F can similarly be applied to form the device 100b including trenched gates 184b shown in FIG. 1B (e.g., if preceded by forming trenches 180 in the semiconductor structure 106) and/or to form the device 100c including silicided gate ohmic contacts 195 shown in FIG. 1C (e.g., by siliciding the upper surface of the gate conductive material 184m before forming the first dielectric material 185m thereon in FIG. 3A).

FIGS. 4A to 4F are schematic cross-sectional views illustrating intermediate fabrication operations in methods of fabricating power semiconductor devices with self-aligned ohmic silicided source contacts according to further embodiments of the present disclosure. Some elements and operations shown in FIGS. 4A to 4F may be similar to those described above with reference to FIGS. 3A to 3F, and thus, similar or overlapping description of such elements and operations may be omitted for brevity.

As shown in FIG. 4A, a semiconductor layer structure 106 including a drift region 120 of a first conductivity type, base/well regions 140/170 of a second conductivity type, source regions 160 of the first conductivity type, and base/well contact regions 188 of the second conductivity type are provided on a substrate 110. A gate insulating material 182m is formed or otherwise provided on the semiconductor layer structure 106, and a gate contact material 184m is formed or otherwise provided on the a gate insulating material 182m opposite the semiconductor layer structure 106.

As shown in FIG. 4B, the gate contact material 184m and the gate insulating material 182m are patterned to form gate insulating layers 182 and gate contacts 184. As shown in FIG. 4C, oxidation (or a conformal deposition) is performed to form a first dielectric material as a silicide blocking layer 185 on sidewalls 184s and on top surfaces of the gate contacts 184 therebetween. If oxidation is used to form the silicide blocking layer 185, the silicide blocking layer 185 may be a silicon dioxide film. That is, instead of depositing a first insulating material 185m (or oxidizing the top surface of the gate contact material 184m) to form the first insulating material 185m, and then etching or otherwise patterning the materials 185m and 184m as a stack (as in the embodiment of FIG. 3B), oxidation or other conformal deposition may be performed to provide silicide blocking layers 185 (such as a silicon dioxide layer) on the sidewalls 184s and the top of the gate contacts 184, after the gate contact material 184m is etched. The first dielectric material of the silicide blocking layers 185 may otherwise be similar to that described above with reference to FIGS. 3A to 3F.

The gate insulating layers 182, gate contacts 184, and silicide blocking layers 185 provide gate stacks or structures 181 that are laterally spaced apart on the semiconductor layer structure 106 with the source region(s) 160 therebetween. The patterning process shown in FIG. 4B defines sidewalls 184s of the gate contacts 184, while the conformal deposition or oxidation process of FIG. 4C defines sidewalls 181s of the gate structure 181. In some embodiments, the gate structures 181 may further include silicide-based gate ohmic contacts 195 (e.g., as shown in FIG. 2C) in the stack, between the top of the gate contact 184 and the silicide blocking layer 185. That is, the gate structures 181 may be a multi-layer stack including the silicide blocking layer 185 and the gate contact 184 (and in some embodiments, a gate ohmic contact 195) encapsulated by the silicide blocking layer 185. The gate ohmic contacts 195 may be TaSi or WSi, both of which have high temperature stability (for subsequent silicidation operations to form the ohmic contacts 190) and can be oxidized (to subsequently form the silicide blocking layer 185).

In FIG. 4C, the top surfaces and sidewalls 184s of the gate contacts 184 are protected from silicidation by the silicide blocking layers 185. However, particularly for oxide-based silicide blocking layers 185, the oxidation temperatures used to create the silicide blocking layers 185 on the sidewalls 184s of the gate contacts 184 in FIG. 4C may not be sufficient to oxidize adjacent surfaces of the WBG semiconductor layer structure 106, resulting in a poor oxide seal and profile at bottom corners of the gate contacts 184 adjacent the interface with the gate insulating layers 182 and the underlying WBG semiconductor layer structure 106.

As such, as shown in FIG. 4D, a second dielectric material is provided on respective sidewalls 181s of the gate structures 181 and patterned to form protective spacers 187 that are self-aligned to the sidewalls 181s of the gate structures 181 The protective spacers 187 extend along the sidewalls 181s and on corner portions of the gate insulating layers 182, directly onto the semiconductor layer structure 106 and free of the gate insulating material 182 therebetween. The deposited thickness of the spacer film and the etchback process are configured to ensure that the spacers 187 are tall enough to cover the sidewalls 181s of the gate structures 181, which in the embodiments of FIGS. 4A to 4F include portions of the silicide blocking layers 185 between the protective spacers 187 and the sidewalls 184s of the gate contacts 184. That is, the protective spacers 187 extend on the side surfaces of (and up to the top surfaces of) the silicide blocking layers 185, and directly onto the surface of the semiconductor layer structure 106 (free of the gate insulating layer 182 therebetween), providing a seal between the protective spacers 187 and the surface of the semiconductor layer structure 106 adjacent the bottom corners of the gate insulating layers 182. The interface between the protective spacers 187 and the surface of the semiconductor layer structure 106 may be sufficient to prevent electrical contact between the gate structure 181 and a conductive silicide 190 formed as an ohmic contact to the source region 160. The second dielectric material of the protective spacers 187 may otherwise be similar to that described above with reference to FIGS. 3A to 3F.

Still referring to FIG. 4D, a conductive silicide 190 (e.g., NiSi) is formed on the source region(s) 160, the well regions 140, and/or the well contact regions 188 of the semiconductor layer structure 106 between adjacent gate structures 181, using a first metal (e.g., Ni) and a first silicide reaction process in a self-aligned manner similar to that described above with reference to FIG. 3D. The low-resistance conductive silicide 190 may continuously extend between adjacent protective spacers 187 on the surface of the semiconductor layer structure 106 (e.g., on up to the entire active area), with the gate contacts 184 free of the conductive silicide 190.

As shown in FIG. 4E, one or more dielectric or ILD layers 186 are formed on the surface of the semiconductor layer structure 106 (covering the ohmic contacts 190 and the gate structures 181) and are patterned to define contact openings 186o that expose the ohmic contacts 190 (and in some embodiments, additional openings (not shown) that expose areas for forming conductive gate pads, using the same mask pattern), similar to the operations of FIG. 3E. As such, portions of the ILD layer(s) 186 are provided on the gate structures 181 and laterally extend onto edges of the ohmic contacts (i.e., the ohmic contacts 190 may extend beyond edges of the openings 186o in the ILD layer(s) 186), but may not completely expose the ohmic contacts 190.

As shown in FIG. 4F, one or more barrier metal layers 194 (e.g., Ti, Al, TiN, Ta, or TaN) may be conformally formed in the contact opening 186o and on surfaces of the ILD layer(s) 186 outside the contact opening 186o, and one or more contact metal layer(s) 196 (e.g., Al, Ti, tantalum (Ta), or tungsten (W)) are formed on the barrier metal layer(s) 194 to substantially fill the contact opening 186o, similar to the operations of FIG. 3F. The contact metal layer(s) 196 may contact less than an entirety of the ohmic contacts 190, due to the lateral extension of the ILD 186 thereon.

The drain contact 192 is also formed (e.g., on a surface of the substrate 110 opposite to the drift region 120), thereby completing the device 200a of FIG. 2A. However, it will be understood that some the operations described in FIGS. 4A to 4F can similarly be applied to form the device 200b including trenched gates 184b shown in FIG. 2B (e.g., if preceded by forming trenches 180 in the semiconductor structure 106) and/or to form the device 200c including silicided gate ohmic contacts 195 shown in FIG. 2C (e.g., by siliciding the upper surface of the gate contacts 184 before forming the silicide blocking layers 185 on the top surface and sidewalls 184s thereof in FIG. 4C).

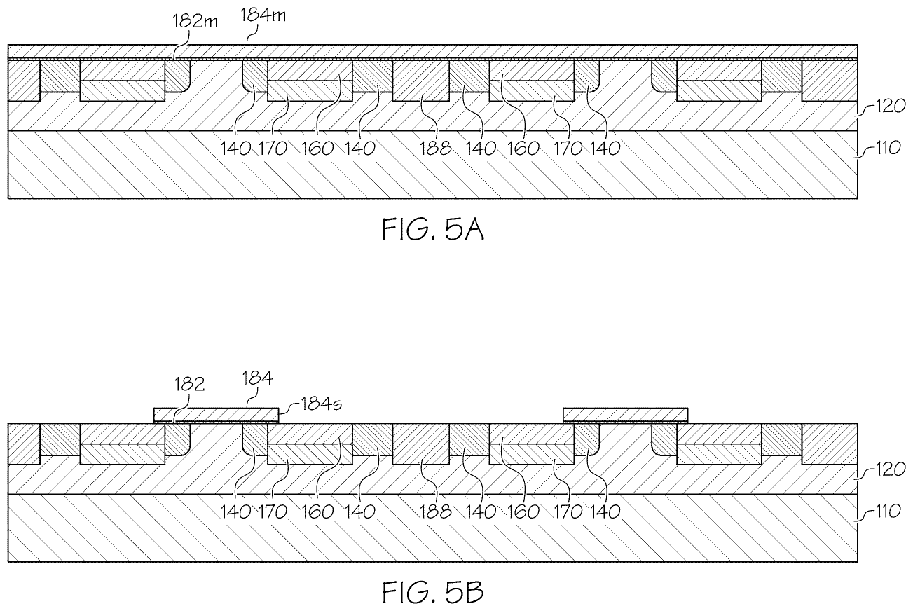

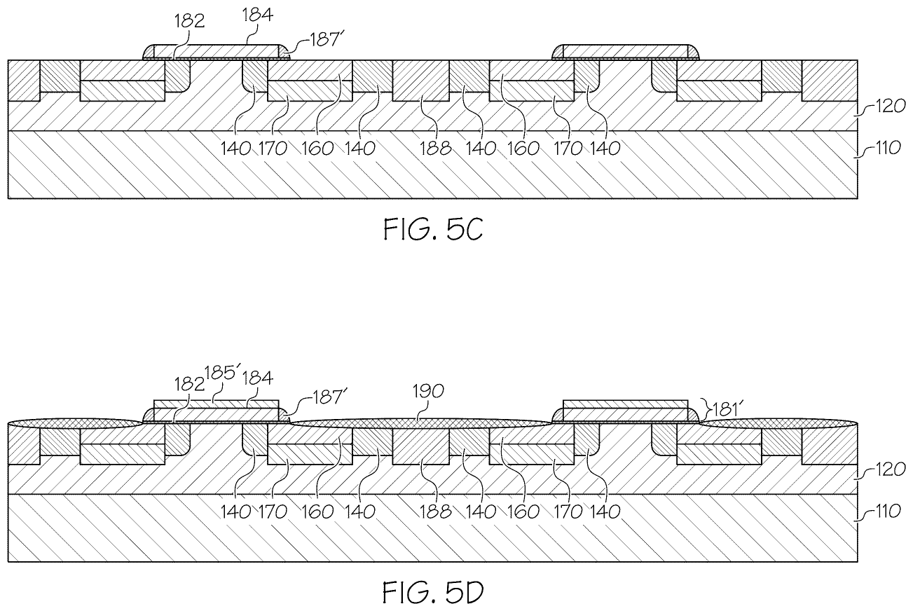

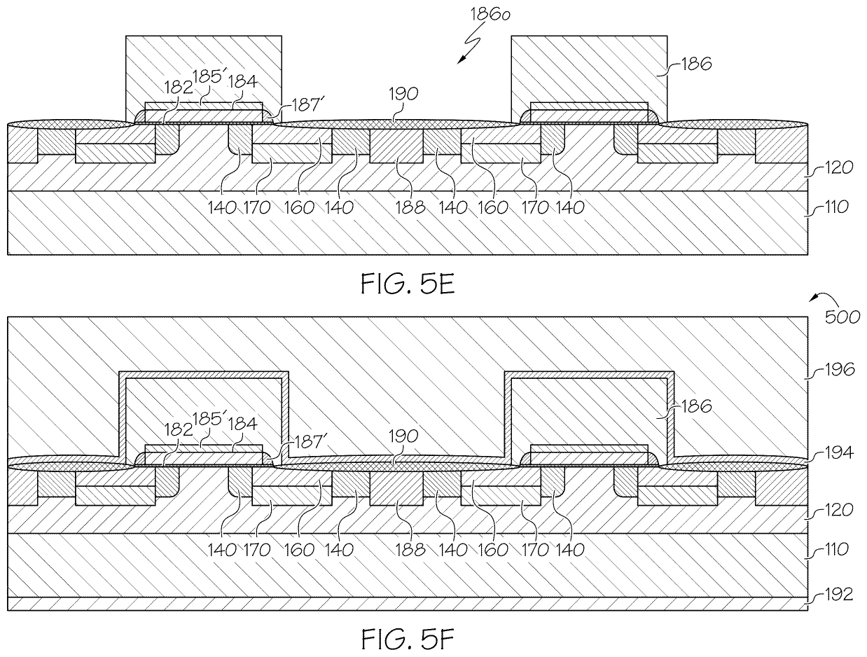

FIGS. 5A to 5F are schematic cross-sectional views illustrating intermediate fabrication operations in methods of fabricating power semiconductor devices with self-aligned ohmic silicided source contacts according to further embodiments of the present disclosure. Some elements and operations shown in FIGS. 5A to 5F may be similar to those described above with reference to FIGS. 4A to 4F, and thus, similar or overlapping description of such elements and operations may be omitted for brevity.

As shown in FIG. 5A, a semiconductor layer structure 106 including a drift region 120 of a first conductivity type, base/well regions 140/170 of a second conductivity type, source regions 160 of the first conductivity type, and base/well contact regions 188 of the second conductivity type are provided on a substrate 110. A gate insulating material 182m is formed or otherwise provided on the semiconductor layer structure 106, and a gate contact material 184m is formed or otherwise provided on the a gate insulating material 182m opposite the semiconductor layer structure 106. As shown in FIG. 5B, the gate contact material 184m and the gate insulating material 182m are patterned to form gate insulating layers 182 and gate contacts 184.

As shown in FIG. 5C, protective spacers 187′ are formed on sidewalls 184s of the gate contacts 184. For example, a dielectric material (e.g., an oxide layer such as TEOS) may be conformally deposited on surfaces of the gate contacts 184 and the semiconductor layer structure 106 therebetween, and an etching process may remove portions of the oxide layer to expose top surfaces of the gate contacts 184 and the semiconductor layer structure 106, leaving the protective spacers 187′ on the sidewalls 184s of the gate contacts 184. The protective spacers 187′ may extend from the sidewalls 184s directly onto the semiconductor layer structure 106 (free of the gate insulating layer 182 therebetween), providing a seal at the interface therebetween that may be sufficient to prevent electrical contact between the gate structure 181 and a conductive silicide 190 formed as an ohmic contact to the source region 160. The deposited thickness of the dielectric material and the etchback process are configured to ensure that the spacers 187′ are tall enough to substantially cover the sidewalls 184s of the gate contacts 184. The dielectric material of the protective spacers 187′ may be an oxide material, a nitride material, or other materials similar to those of the protective spacers 187 described above.

As shown in FIG. 5D, silicide blocking layers 185′ are formed on top surfaces of the gate contacts 184 between the protective spacers 187′. That is, the protective spacers 187′ may be formed before the silicide blocking layers 185′. For example, an oxidation process may be performed (e.g., at a relatively low temperature and a relatively short duration to avoid diffusion or growth on the semiconductor layer structure) to form the silicide blocking layers 185′ on the surfaces of the gate contacts 184 that are exposed by the protective spacers 187′. If oxidation is used to form the silicide blocking layer 185′, the silicide blocking layer 185′ may be a silicon dioxide film. The oxidation process may be performed such that the silicide blocking layers 185′ contact the protective spacers 187′ at edges of the top surfaces of the gate contacts 184. As such, the sidewalls 184s of the gate contacts 184 are covered by the protective spacers 187′, while the top surfaces of the gate contacts 184 are covered by the silicide blocking layers 185′, defining the gate structure 181′. In some embodiments, the dielectric materials of the silicide blocking layers 185′ (e.g., SiO or other oxide-based materials) and the protective spacers 187′ (e.g., SiN or other nitride-based materials) may be different.

Still referring to FIG. 5D, a conductive silicide 190 (e.g., NiSi) is formed on the source region(s) 160, the well regions 140, and/or the well contact regions 188 of the semiconductor layer structure 106 between adjacent gate structures 181, using a first metal and a first silicide reaction process in a self-aligned manner similar to that described above with reference to FIG. 3D. The low-resistance conductive silicide 190 may continuously extend between adjacent protective spacers 187 on the surface of the semiconductor layer structure 106 (e.g., on up to the entire active area), with the gate contacts 184 free of the conductive silicide 190, and without the use of additional masking operations.

As shown in FIG. 5E, one or more dielectric or ILD layers 186 are formed on the surface of the semiconductor layer structure 106 (covering the ohmic contacts 190 and the gate structures 181) and are patterned to define contact openings 186o that expose the ohmic contacts 190 (and in some embodiments, additional openings (not shown) that expose areas for forming conductive gate pads, using the same mask pattern), similar to the operations of FIG. 4E. As such, portions of the ILD layer(s) 186 are provided on the gate structures 181 and laterally extend onto edges of the ohmic contacts (i.e., the ohmic contacts 190 may extend beyond edges of the openings 186o in the ILD layer(s) 186), but may not completely expose the ohmic contacts 190.

As shown in FIG. 5F, one or more barrier metal layers 194 may be conformally formed in the contact opening 186o and on surfaces of the ILD layer(s) 186 outside the contact opening 186o, and one or more contact metal layer(s) are formed on the barrier metal layer(s) 194 to substantially fill the contact opening 186o, similar to the operations of FIG. 4F. The contact metal layer(s) 196 may contact less than an entirety of the ohmic contacts 190, due to the lateral extension of the ILD 186 thereon. The drain contact 192 is also formed on a surface of the substrate 110 opposite to the drift region 120, thereby completing the device 500.

FIGS. 6A to 6F are schematic cross-sectional views illustrating intermediate fabrication operations in methods of fabricating power semiconductor devices with self-aligned ohmic silicided source contacts according to further embodiments of the present disclosure. Some elements and operations shown in FIGS. 6A to 6F may be similar to those described above with reference to FIGS. 5A to 5F, and thus, similar or overlapping description of such elements and operations may be omitted for brevity.

As shown in FIG. 6A, a semiconductor layer structure 106 is provided on a substrate 110, a gate insulating material 182m is formed or otherwise provided on the semiconductor layer structure 106, and a gate contact material 184m is formed or otherwise provided on the a gate insulating material 182m opposite the semiconductor layer structure 106. As shown in FIG. 6B, the gate contact material 184m and the gate insulating material 182m are patterned to form gate insulating layers 182 and gate contacts 184.

As shown in FIG. 6C, protective spacers 187′ or 187″ are formed on sidewalls 184s of the gate contacts 184. For example, one or more dielectric materials may be conformally deposited on surfaces of the gate contacts 184 and the semiconductor layer structure 106 therebetween, and one or more etching processes may remove portions of the dielectric materials to expose top surfaces of the gate contacts 184 and the semiconductor layer structure 106, leaving the protective spacers 187′ or 187″ on the sidewalls 184 s of the gate contacts 184.

In particular, in some embodiments, a nitride layer (such as SiN) may be deposited and etched to form the protective spacers 187′ on the sidewalls 184s of the gate contacts 184. In other embodiments, the protective spacers 187″ may be formed to include first and second dielectric material layers (e.g., an oxide layer (such as TEOS) and a nitride layer (such as SiN), or vice versa) may be sequentially deposited and etched to form the protective spacers 187″ including first and second layers of different dielectric materials (e.g., a TEOS spacer with conformal SiN spacer thereon). The protective spacers 187′, 187″ may extend from the sidewalls 184s directly onto the semiconductor layer structure 106 (free of the gate insulating layer 182 therebetween), providing a seal at respective interfaces therebetween so as to prevent electrical contact between the gate structure 181 and a conductive silicide 190 formed as an ohmic contact to the source region 160. The deposited thickness of the dielectric material(s) and the etchback process(es) are configured to ensure that the spacers 187′, 187″ are tall enough to substantially cover the sidewalls 184s of the gate contacts 184.

As shown in FIG. 6D, silicide blocking layers 185′ are formed on top surfaces of the gate contacts 184 between the protective spacers 187′ or 187″, for example, using an oxidation process at a relatively low temperature and of a relatively short duration to avoid diffusion or growth on the semiconductor layer structure 106, in a manner similar to that described above with reference to FIG. 5D. As such, the sidewalls 184s of the gate contacts 184 are covered by the protective spacers 187′ or 187″, while the top surfaces of the gate contacts 184 are covered by the silicide blocking layers 185′. In the example of FIGS. 6A to 6F, the protective spacers 187′ or 187″ include at least one dielectric material (e.g., SiN or other nitride-based materials) that differs from (and thus, has etch selectivity with respect to) the dielectric material of the silicide blocking layers 185′ (e.g., SiO or other oxide-based materials).

Still referring to FIG. 6D, a conductive silicide 190 (e.g., NiSi) is formed on the source region(s) 160, the well regions 140, and/or the well contact regions 188 of the semiconductor layer structure 106 between adjacent gate structures 181, using a first metal and a first silicide reaction process (e.g., at higher annealing temperatures of greater than 900° C.) in a self-aligned manner similar to that described above with reference to FIG. 3D. The low-resistance conductive silicide 190 may thereby continuously extend between adjacent protective spacers 187′ or 187″ on the surface of the semiconductor layer structure 106 (e.g., on up to the entire active area) with no additional masking steps.

As shown in FIG. 6E, a selective etching process is performed to remove the silicide blocking layers 185′ from the top surfaces of the gate contacts 184 between the protective spacers 187′ or 187″, and a second metal (e.g., a low-temperature silicide metal, such as titanium) may be deposited on the top surfaces of the gate contacts 184 and silicided to form gate ohmic contacts 195′, thereby providing gate structures 181″. The gate ohmic contacts 195′ are formed of a second conductive silicide that is different from the first conductive silicide of the WBG ohmic contacts 190.

For example, after forming the WBG ohmic contacts 190 on the semiconductor layer structure 106 between the gate contacts 184, the silicide blocking layers 185′ may be removed by a wet etching process, the second metal (e.g., Ti) may be deposited on the top of the gate contacts 184 opposite the semiconductor layer structure 106, and a second silicide reaction process (e.g., at annealing temperatures lower than those used in the first silicide reaction process, e.g., at less than 850° C.) may be performed on the second metal to form second conductive silicide-based gate ohmic contacts 195′ on the gate contacts 184. The second silicide reaction process may include a first silicide reaction anneal (e.g., RTA1), a wet etching process to remove unreacted portions of the second metal, and a second silicide reaction anneal (e.g., RTA2) may be performed to convert the conductive silicide into a low-resistance form (e.g., TiSi) to provide the gate ohmic contacts 195′.

The low-temperature silicide-based gate ohmic contacts 195′ may be formed from materials (such as TiSi) that may provide lower resistance than the gate ohmic contacts 195 (such as TaSi or WSi) of FIG. 1C. More generally, as the higher temperature silicides for the WBG ohmic contacts 190 were previously formed in FIG. 6D, the metal(s) and/or fabrication conditions (including anneal temperature(s)) for the gate ohmic contacts 195′ can be independently selected so as to optimize resistance, current distribution, and/or other characteristics. In other words, the operations of FIGS. 6A to 6F may allow for fabrication of gate ohmic contacts 195′ with lower resistance metal silicide gate contacts 195′ thereon, as any desired higher-temperature anneal operations (which can cause migration and/or agglomeration of the low-temperature metal silicides) have been previously performed.

In removing the silicide blocking layers 185′ described herein, it may be critical for the second dielectric material (e.g., SiN) of the protective spacers 187′, 187″ to also provide a seal at the interface with the sidewalls 184s of the gates 184, as wet etching operations to remove the silicide blocking layers 185′ may wick down the gate sidewalls 184s and cause GOI issues, particularly when the silicide blocking layers 185′ are formed using high temperature oxide (HTO) deposition. Also, it may be critical for the second silicide operations (to form the gate ohmic contacts 195′) to be less than 850° C. (e.g., less than 800° C.) to reduce or prevent migration of the second metal (e.g., Ti) and/or mixing of the second metal (e.g., Ti) with the first conductive silicide (e.g., NiSi) of the WBG ohmic contact regions 190.

As shown in FIG. 6F, one or more dielectric or ILD layers 186 are formed on the surface of the semiconductor layer structure 106 (covering the ohmic contacts 190 and the gate structures 181), and are patterned to define contact openings that expose the ohmic contacts 190 (and in some embodiments, additional openings (not shown) that expose areas for forming conductive gate pads, using the same mask pattern), similar to the operations of FIG. 5E. One or more barrier metal layers 194 may be conformally formed in the contact opening 186o and on surfaces of the ILD layer(s) 186 outside the contact opening 186o, and one or more contact metal layer(s) are formed on the barrier metal layer(s) 194 to substantially fill the contact opening 186o, similar to the operations of FIG. 4F. The drain contact 192 is also formed on a surface of the substrate 110 opposite to the drift region 120, thereby completing the device 600.

The example processes shown in FIGS. 3A to 3F, 4A to 4F, 5A to 5F, and 6A to 6F are illustrated by way of example to form planar transistor device structures 100a, 100c, 200a, 200c, 400, 500, 600. However, it will be understood that the trenched transistor device structures 100b, 200b of FIGS. 1B and 2B may be formed by implementing similar fabrication operations before or after forming gate trenches 180 in the semiconductor layer structure 106.

In the example embodiments of FIGS. 1A to 6F, due to the self-aligned processes described herein, up to an entirety of the surface of the WBG semiconductor layer structure 106 between adjacent gate structures 181 may be silicided to form the WBG ohmic contacts 190, providing significantly more ohmic contact area than a fabrication process using a masked blocking layer on the gate structures 181 or fabrication operations that form silicided ohmic contact regions only on regions of the semiconductor layer structure 106 that are exposed by openings 186o in a deposited interlayer dielectric (ILD) layer 186 (i.e., only under the final metal contact 196 to the source 160/well contact 188 regions). Implementation of the silicidation operations before deposition of the interlayer dielectric (ILD) insulator 186 may also allow for independent optimization of characteristics of the gates 184 and/or the WBG ohmic contacts 190. For example, ohmic contacts 190 and 195 for each region (source 160 and gate 184) can be selectively blocked from unwanted silicide deposition; the silicide metal(s) for one region can be selected independently from the silicide metal(s) selected for the other regions; and respective anneal temperatures or other processing conditions can be optimized for the particular silicide metal(s) selected for a particular region.

Power semiconductor devices according to embodiments of the present disclosure may provide several advantages over contact configurations and fabrication methods of existing power semiconductor devices. For example, silicided contacts as described herein can provide increased ohmic contact area (and thus lower Rsp) for WBG power semiconductor devices, by using self-aligned techniques that provide WBG-silicide-blocking on polysilicon surfaces. Embodiments of the present disclosure may thereby increase or maximize the area of the WBG ohmic contact regions, thereby reducing resistance and improving current distribution. Embodiments of the present disclosure may provide more compact cell design (e.g., with smaller design rules) in any WBG power device cell architecture, including vertical or lateral power devices, with n-type and p-type contacts to SiC or other wide bandgap semiconductor contact regions, in planar or trenched gate configurations.

It will be appreciated that features of the different embodiments disclosed herein may be combined in any way to provide many additional embodiments. Also, while the present invention is described above primarily with respect to power MOSFET implementations, it will be appreciated that the techniques described herein apply equally well to other similar power semiconductor devices. Thus, embodiments of the present invention are not limited MOSFETs, and the techniques disclosed herein may be used on IGBTs or any other appropriate device. For example, features of any MOSFET embodiment described herein may be incorporated into IGBT embodiments fabricated on SiC, or other semiconductor materials, for example, Si. Thus, it will be appreciated that various features of the inventive concepts are described herein with respect to specific examples, but that these features may be added to other embodiments and/or used in place of example features of other embodiments to provide many additional embodiments. The present invention should therefore be understood to encompass these different combinations.

In the description above, each example embodiment is described with reference to regions of particular conductivity types. It will be appreciated that opposite conductivity type devices may be formed by simply reversing the conductivity of the n-type and p-type layers in each of the above embodiments. Thus, it will be appreciated that the present invention covers both n-channel and p-channel devices for each different device structure (e.g., MOSFET, IGBT, etc.).

The present invention has primarily been discussed above with respect to silicon carbide based power semiconductor devices. It will be appreciated, however, that silicon carbide is used herein as an example and that the devices discussed herein may be formed in any appropriate wide bandgap semiconductor material system. As an example, gallium nitride based semiconductor materials (e.g., gallium nitride, aluminum gallium nitride, etc.) may be used instead of silicon carbide in any of the embodiments described above. More generally, while discussed with reference to silicon carbide devices, embodiments of the present invention are not so limited, and may have applicability to devices formed using other wide bandgap semiconductor materials, for example, gallium nitride, zinc selenide, or any other II-VI or III-V wide bandgap compound semiconductor materials.

Embodiments of the present invention have been described above with reference to the accompanying drawings, in which embodiments of the invention are shown. It will be appreciated, however, that this invention may, however, be embodied in many different forms and should not be construed as limited to the embodiments set forth above. Rather, these embodiments are provided so that this disclosure will be thorough and complete, and will fully convey the scope of the invention to those skilled in the art. Like numbers refer to like elements throughout.

Herein, a first element (e.g., a contact, layer or region) of a semiconductor device “vertically overlaps” a second element of the semiconductor device if an axis that is perpendicular to a surface of the semiconductor layer structure of the device (e.g., in a vertical direction) extends through both the first element and the second element.

It will be understood that, although the terms first, second, etc. are used throughout this specification to describe various elements, these elements should not be limited by these terms. These terms are only used to distinguish one element from another. For example, a first element could be termed a second element, and, similarly, a second element could be termed a first element, without departing from the scope of the present invention. The term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “top” or “bottom” may be used herein to describe a relationship of one element, layer or region to another element, layer or region as illustrated in the figures. It will be understood that these terms are intended to encompass different orientations of the device in addition to the orientation depicted in the figures.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Embodiments of the invention are also described with reference to fabrication operations. It will be appreciated that the steps shown in the fabrication operations need not be performed in the order shown.

Some embodiments of the invention are described with reference to semiconductor layers and/or regions which are characterized as having a conductivity type such as n-type or p-type, which refers to the majority carrier concentration in the layer and/or region. Thus, n-type material has a majority equilibrium concentration of negatively charged electrons, while p-type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, there have been disclosed typical embodiments of the invention and, although specific terms are employed, they are used in a generic and descriptive sense only and not for purposes of limitation, the scope of the invention being set forth in the following claims.

1. A power semiconductor device, comprising:
a semiconductor layer structure comprising a drift region of a first conductivity type;
a gate structure comprising a gate contact on the semiconductor layer structure and a silicide blocking layer on the gate contact opposite the semiconductor layer structure; and
a protective spacer on a sidewall of the gate structure, wherein the protective spacer is directly on the semiconductor layer structure.

2. The power semiconductor device of claim 1, wherein the protective spacer comprises a different material than the silicide blocking layer.

3. The power semiconductor device of claim 2, wherein the protective spacer extends onto a sidewall of the silicide blocking layer.

4. The power semiconductor device of claim 1, wherein the gate structure comprises first and second gate structures on the semiconductor layer structure with at least one source region therebetween, and the protective spacer comprises first and second protective spacers on adjacent sidewalls of the first and second gate structures, respectively, and further comprising:
a first conductive silicide on the at least one source region and continuously extending from the first protective spacer to the second protective spacer.

5. The power semiconductor device of claim 4, further comprising:
an interlayer dielectric layer on the first and second gate structures and comprising an opening therein that exposes the at least one source region,
wherein the first conductive silicide extends beyond edges of the at least one opening in the interlayer dielectric layer and between the interlayer dielectric layer and the semiconductor layer structure.

6. The power semiconductor device of claim 4, wherein the semiconductor layer structure further comprises a well contact region of a second conductivity type between the first and second gate structures, and the first conductive silicide is on the well contact region.

7. The power semiconductor device of claim 1, wherein the silicide blocking layer extends on the sidewall between the gate contact and the protective spacer.

8. The power semiconductor device of claim 1, wherein the protective spacer comprises first and second layers of different dielectric materials.

9. The power semiconductor device of claim 4, wherein the gate contact comprises polysilicon and is free of the first conductive silicide.

10. The power semiconductor device of claim 9, wherein the gate contact further comprises a second conductive silicide between the polysilicon and the silicide blocking layer, wherein the second conductive silicide is different from the first conductive silicide.

11. The power semiconductor device of claim 10, wherein the semiconductor layer structure comprises silicon carbide, wherein the first conductive silicide comprises nickel, and wherein the second conductive silicide comprises at least one of tantalum, tungsten, titanium, or cobalt.

12. A power semiconductor device, comprising:
a semiconductor layer structure comprising a drift region of a first conductivity type and a source region of the first conductivity type;
a gate structure on the semiconductor layer structure adjacent the source region, the gate structure comprising a gate contact and a silicide blocking layer on the gate contact opposite the semiconductor layer structure;
an interlayer dielectric layer on the gate structure and comprising an opening therein that exposes the source region; and
a first conductive silicide on the source region and extending beyond edges of the opening in the interlayer dielectric layer and between the interlayer dielectric layer and the semiconductor layer structure.

13. The power semiconductor device of claim 12, further comprising:
a protective spacer on a sidewall of the gate structure, wherein the protective spacer is directly on the semiconductor layer structure.

14. The power semiconductor device of claim 13, wherein:
the gate structure comprises first and second gate structures on the semiconductor layer structure with the source region therebetween;
the protective spacer comprises first and second protective spacers on adjacent sidewalls of the first and second gate structures, respectively; and
the first conductive silicide continuously extends from the first protective spacer to the second protective spacer.

15. The power semiconductor device of claim 13, wherein the protective spacer comprises a different material than the silicide blocking layer.

16. The power semiconductor device of claim 15, wherein the protective spacer extends onto a sidewall of the silicide blocking layer, and a top portion of the gate structure opposite the semiconductor layer structure is free of the protective spacer.

17. A power semiconductor device, comprising:
a semiconductor layer structure comprising a drift region of a first conductivity type, and at least one source region of the first conductivity type;
gate contacts on the semiconductor layer structure with the at least one source region therebetween;
protective spacers on respective sidewalls of the gate contacts, wherein top portions of the gate contacts opposite the semiconductor layer structure are free of the protective spacers;
an interlayer dielectric layer on the top portions of the gate contacts; and
a first ohmic contact on the at least one source region and continuously extending between the protective spacers.

18. The power semiconductor device of claim 17, further comprising:
silicide blocking layers between the interlayer dielectric layer and the top portions of the gate contacts.

19. The power semiconductor device of claim 18, wherein the protective spacers comprise a different material than the silicide blocking layers and extend onto side surfaces thereof.

20. The power semiconductor device of claim 17, wherein the first ohmic contact comprises a first conductive silicide, and the gate contacts are free of the first conductive silicide.

21. The power semiconductor device of claim 20, further comprising:
second ohmic contacts comprising a second conductive silicide between the interlayer dielectric layer and the top portions of the gate contacts,
wherein the second conductive silicide is different from the first conductive silicide.

22. The power semiconductor device of claim 21, wherein the protective spacers respectively comprise first and second layers of different dielectric materials.

23. The power semiconductor device of claim 17, wherein the protective spacers are directly on the semiconductor layer structure.

24. A method of fabricating a semiconductor device, the method comprising:
providing a semiconductor layer structure comprising a drift region of a first conductivity type and at least one source region of the first conductivity type;
providing gate contacts on the semiconductor layer structure;
providing a first dielectric material on the gate contacts opposite the semiconductor layer structure as silicide blocking layers;
providing a second dielectric material on respective sidewalls of the gate contacts as protective spacers; and
providing a first conductive silicide on the at least one source region between the gate contacts.

25.-35. (canceled)

36. A method of fabricating a semiconductor device, the method comprising:
providing a semiconductor layer structure comprising a drift region of a first conductivity type and at least one source region of the first conductivity type;
providing a gate insulating material on the semiconductor layer structure;
providing a gate contact material on the gate insulating material opposite the semiconductor layer structure;
providing a first dielectric material on the gate contact material opposite the gate insulating material; and
patterning the first dielectric material, the gate contact material, and the gate insulating material to form gate structures comprising gate contacts and silicide blocking layers thereon that are spaced apart on the semiconductor layer structure with the at least one source region therebetween.

37.-42. (canceled)
